(19) United States
(12) Patent Application Publication
(10) Pub. No.: US 2004/0233771 A1
(43) Pub. Date: Nov. 25, 2004

(54) Stack element circuit

(76) Inventors: Joseph S. Shor, Tel Mond (IL); Eduardo Maayan, Kfar Saba (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/880,586

(22) Filed: Jul. 1, 2004

Related U.S. Application Data
(62) Division of application No. 09/983,511, filed on Oct. 24, 2001, now Pat. No. 6,791,396.

(51) Int. Cl. G11C 8/02

(52) U.S. Cl. 365/232

(57) ABSTRACT

A circuit including a reference element adapted to provide a reference current and having a control terminal and a first terminal, there being a voltage (Vct) between the control terminal and the first terminal of the reference element, and a plurality of series-connected stack elements, each the stack element including a first terminal connected to a first voltage, and a control terminal connected to a second terminal, the stack elements being adapted to receive at least one of the reference current and a multiple of the reference current, the stack elements and the reference element being matched such that a voltage between the control terminal and the first terminal of at least one of the stack elements is generally the same as Vct.

### FIELD OF THE INVENTION

The present invention relates generally to circuitry for memory cell arrays, such as circuitry that may be used for voltage regulators for erasable, programmable read only memories (EPROMs), electrically erasable, programmable read only memories (EEPROMs), and flash EEPROM memories, for example.

### BACKGROUND OF THE INVENTION

Voltage regulators are circuits useful for providing accurate analog voltages for erasable, programmable read only memories (EPROMs) and other integrated circuits. A voltage regulator may typically comprise a reference voltage, a comparator, a driver and a resistor divider. An example of a prior art voltage regulator is shown in FIG. 1, and uses a so-called Miller architecture, well known in the art. A comparator GM₁ is connected to the gate of a PMOS (p-channe metal oxide semiconductor) driver GM₂. The comparator GM₁ is supplied a supply voltage VPP, and compares voltages IP and FB. The comparator GM₁ adjusts the gate voltage of the PMOS driver GM₂ to equalize voltages IP and FB. The output voltage, OP, is thus a multiple of the input voltage, IP. The multiplication factor is determined by the resistor divider (RD) ratio between OP and FB.

A problem with this type of regulator is that a large current (typically >100 μA) is required across the resistor divider RD in order to establish the multiplication factor. It is possible to make this current arbitrarily small by increasing the resistance of the divider. However, this may have several undesirable effects. First, the drive capability of the regulator may be lowered. Second, increasing the resistance may require significant silicon area. Third, the speed of the feedback is a function of the current, and as such, lowering the current may substantially degrade the regulator's stability.

In EPROM applications, the VPP supply (FIG. 1) is usually a pumped voltage. Pumping from the chip supply (VDD) to a higher voltage (VPP) is a process that has a low efficiency. Any current consumption from VPP requires a significantly larger current consumption from VDD, usually by a factor of 5-10. As such, it is critical to conserve current in regulators operating from a boosted source, such as those providing the wordline voltage in EPROMs. In the regulator of FIG. 1, the resistor divider drains current from the VPP supply, such that a current of 100 μA required across the resistor divider may mean a VDD current of 1 mA.

Accordingly, there is a need for a regulator that has a low current consumption from VPP or another supply, while providing a high drive capability.

### SUMMARY OF THE INVENTION

The present invention seeks to provide a stack element circuit that may be used to provide an improved voltage regulator. The present invention may comprise stacked diode-connected transistors that receive a reference current or a multiple thereof from a reference element, which may be a reference transistor. Diode-connected transistors are transistors whose gate is connected to the drain. The diode-connected transistors and the reference element are preferably matched such that a gate-source voltage of the diode-connected transistors is generally the same as the gate-source voltage of the reference element.

There is thus provided in accordance with a preferred embodiment of the present invention a circuit including a reference element adapted to provide a reference current and having a control terminal and a first terminal, there being a voltage (Vct) between the control terminal and the first terminal of the reference element, and a plurality of series-connected stack elements, each the stack element including a first terminal connected to a first voltage, and a control terminal connected to a second terminal, the stack elements being adapted to receive at least one of the reference current and a multiple of the reference current, the stack elements and the reference element being matched such that a voltage between the control terminal and the first terminal of at least one of the stack elements is generally the same as Vct.

In accordance with a preferred embodiment of the present invention a voltage between the control terminal and the first terminal of each the stack element is generally the same as Vct.

Further in accordance with a preferred embodiment of the present invention one of the first and second terminals comprises an input and the other of the first and second terminals comprises an output, and the output of a first stack element is connected to the input of a subsequent stack element.

Still further in accordance with a preferred embodiment of the present invention the reference element is at a voltage Vdd and the stack elements are at voltage Vpp wherein Vpp≧Vdd.

In accordance with a preferred embodiment of the present invention the stack elements include diode-connected transistors and the reference element includes a transistor, the diode-connected transistors and the reference element being matched such that a gate-source voltage of the diode-connected transistors is generally the same as Vct.

Further in accordance with a preferred embodiment of the present invention the reference element is adapted to have a fixed Vct voltage.

Still further in accordance with a preferred embodiment of the present invention the circuit includes a voltage regulator having an input and an output, wherein the input is a control terminal of the reference element, and the output is an output of a top transistor of the stack, the top transistor being the first of the diode-connected transistors that receives the reference current.

In accordance with a preferred embodiment of the present invention the first terminal includes an input and the second terminal includes an output.

In accordance with a preferred embodiment of the present invention the stack elements and the reference element include NMOS (n-channel metal oxide semiconductor) transistors, and the first terminal includes an input including at least one of a source and bulk, the control terminal includes a gate, and the second terminal includes an output including a drain.

Further in accordance with a preferred embodiment of the present invention the reference element receives a reference voltage at the control terminal and the output generates the reference current.

Still further in accordance with a preferred embodiment of the present invention the stack elements and the reference element include NMOS transistors, wherein for each NMOS transistor, a resistor is connected between a source of the transistor and the first terminal, a bulk of the transistor is connected to at least one of the source and the first terminal, the control terminal includes a gate, the first terminal comprises an input of the stack element and the second terminal includes an output including a drain.

Additionally in accordance with a preferred embodiment of the present invention an input of the reference element is at ground (GND).

In accordance with a preferred embodiment of the present invention an output of the circuit is the output of the top stack element, the top stack element being the first of the stack elements that receives the reference current.

Further in accordance with a preferred embodiment of the present invention a bottom stack element, the bottom stack element being the last of the stack elements that receives the reference current, receives a second reference voltage at its input.

Still further in accordance with a preferred embodiment of the present invention the stack elements and the reference element include NMOS transistors, and the first terminal includes an input including at least one of a source and bulk, the control terminal includes a gate, and the second terminal includes an output including a drain, wherein the reference element receives a reference voltage at the control terminal and the output generates the reference current, wherein an input of the reference element is at ground (GND), wherein an output of the circuit is the output of the top stack element, the top stack element being the first of the stack elements that receives the reference currents and wherein a bottom stack element, the bottom stack element being the last of the stack elements that receives the reference current, receives a second reference voltage at its input.

In accordance with another preferred embodiment of the present invention the first terminal includes an output and the second terminal includes an input.

Further in accordance with a preferred embodiment of the present invention the stack elements and the reference element include PMOS (p-channel metal oxide semiconductor) transistors, and the first terminal includes an output including at least one of a source and bulk, the control terminal includes acetate, and the second terminal includes an input including a drain.

Still further in accordance with a preferred embodiment of the present invention the stack elements and the reference element include PMOS transistors, wherein for each PMOS transistor, a resistor is connected between a source of the transistor and the first terminal, a bulk of the transistor is connected to at least one of the source and the first terminal, the control terminal includes a gate, the first terminal comprises an input of the stack element and the second terminal includes an input including a drain.

Additionally in accordance with a preferred embodiment of the present invention the control terminal and the input of the reference element are at GND.

In accordance with a preferred embodiment of the present invention a reference voltage is placed at the output of the reference element.

Further in accordance with a preferred embodiment of the present invention the control terminal of a bottom stack element, the bottom stack element being the last of the stack elements that receives the reference current, receives a second reference voltage and the input of the bottom stack element is at GND.

Still further in accordance with a preferred embodiment of the present invention the stack elements and the reference element include PMOS transistors, and the first terminal includes an output including at least one of a source and bulk, the control terminal includes a gate, and the second terminal includes an input including a drain, wherein the control terminal and the input of the reference element are at GND, wherein a reference voltage is placed at the output of the reference element, wherein an output of the circuit is the output of the top stack element, the top stack element being the first of the stack elements that receives the reference current, and wherein the control terminal of a bottom stack element, the bottom stack element being the last of the stack elements that receives the reference current, receives a second reference voltage and the input of the bottom stack element is at GND.

In accordance with a preferred embodiment of the present invention the reference element is connected to the stack elements via a current mirror.

Further in accordance with a preferred embodiment of the present invention the current mirror includes at least two matched transistors.

Still further in accordance with a preferred embodiment of the present invention a voltage across the stack elements includes the Vct multiplied by a number of the stack elements.

In accordance with a preferred embodiment of the present invention a first reference voltage (VREF) is input to the reference element.

Further in accordance with a preferred embodiment of the present invention a second reference voltage is input to the stack elements.

Still further in accordance with a preferred embodiment of the present invention the second reference voltage includes the first reference voltage divided by a voltage divider.

Additionally in accordance with a preferred embodiment of the present invention the second reference voltage is equal to the first reference voltage divided by a predetermined factor Y, and wherein an output OP of the circuit is given by OP=(S×VREF)+(VREFN) wherein S=the number of stack elements.

In accordance with a preferred embodiment of the present invention the voltage divider includes a resistor divider. The resistor divider may be buffered by a buffer. The output of the buffer may be input to the stack elements. The resistor divider may include a variable resistor divider or a digitally controlled resistor divider, for example.

Further in accordance with a preferred embodiment of the present invention there is a shunting path to at least one of the stack elements.

There is also provided in accordance with a preferred embodiment of the present invention a driver including first and second PMOS transistors, first and second NMOS transistors, and first and second current sources, wherein a gate and a drain of the first PMOS transistor are connected to the first current source, and the first current source is grounded, and wherein a source of the first PMOS transistor is connected to a source of the first NMOS transistor, the first NMOS transistor having its gate and its drain connected to the second current source, the second current source being connected to a supply voltage, and wherein gates of the NMOS transistors are connected to each other, and gates of the PMOS transistors are connected to each other, and wherein a drain of the second NMOS transistor is connected to the supply voltage and a source of the second NMOS transistor is connected to an output of the driver, and wherein a drain of the second PMOS transistor is connected to GND, and a source of the second PMOS transistor is connected to the output of the driver.

In accordance with a preferred embodiment of the present invention the first and second current sources are derivable from a reference current.

Further in accordance with a preferred embodiment of the present invention the first and second current sources are generally equal.

Still further in accordance with a preferred embodiment of the present invention an input to the driver is connected to an output of a circuit including a reference element adapted to provide a reference current and having a control terminal and a first terminal, there being a voltage (Vct) between the control terminal and the first terminal of the reference element, and a plurality of series-connected stack elements, each the stack element including a first terminal connected to a first voltage, and a control terminal connected to a second terminal, the stack elements being adapted to receive at least one of the reference current and a multiple of the reference current, the stack elements and the reference element being matched such that a voltage between the control terminal and the first terminal of at least one of the stack elements is generally the same as Vct, wherein a first reference voltage (VREF) is input to the reference element, and wherein a second reference voltage is input to the stack elements.

There is also provided in accordance with a preferred embodiment of the present invention a circuit including a reference element adapted to receive a first reference voltage and provide a reference current, and a plurality of series-connected stack elements adapted to receive the reference current and provide a multiple of the first reference voltage, wherein the multiple is a function of the number of the stack elements.

### BRIEF DESCRIPTION OF THE DRAWINGS

The present invention will be understood and appreciated more fully from the following detailed description taken in conjunction with the appended drawings in which:

FIG. 1 is a schematic illustration of a prior art voltage regulator;

FIG. 2 is a schematic illustration of a general circuit comprising stack elements, which may be used as a voltage regulator circuit, constructed and operative in accordance with a preferred embodiment of the present invention;

FIG. 3 is a schematic illustration of a voltage regulator constructed and operative in accordance with a preferred embodiment of the present invention, and using NMOS transistors;

FIG. 4 is a schematic illustration of the voltage regulator of FIG. 3, illustrating diode-connected transistor circuitry, circuitry of a driver, and a circuit to generate a V_{OFFSET} input used in the regulator of FIG. 3;

FIG. 5 is a schematic illustration of another version of the voltage regulator of FIG. 3, constructed and operative in accordance with another preferred embodiment of the present invention, and including digital control of the V_{OFFSET} input and the number of stack elements in the circuit;

FIG. 6 is a graphical illustration of a rise and fall of an output voltage of the voltage regulator of FIG. 5, in accordance with a preferred embodiment of the present invention;

FIG. 7 is a schematic illustration of yet another version of the voltage regulator of FIG. 3, constructed and operative in accordance with yet another preferred embodiment of the present invention, and including PMOS transistors;

FIGS. 8 and 9 are schematic illustrations of stack elements of the general circuit of FIG. 2, which comprises NMOS transistors, in accordance with a preferred embodiment of the present invention, respectively without and with a resistor; and

FIGS. 10 and 11 are schematic illustrations of stack elements of the general circuit of FIG. 2, which comprises PMOS transistors, in accordance with a preferred embodiment of the present invention, respectively without and with a resistor.

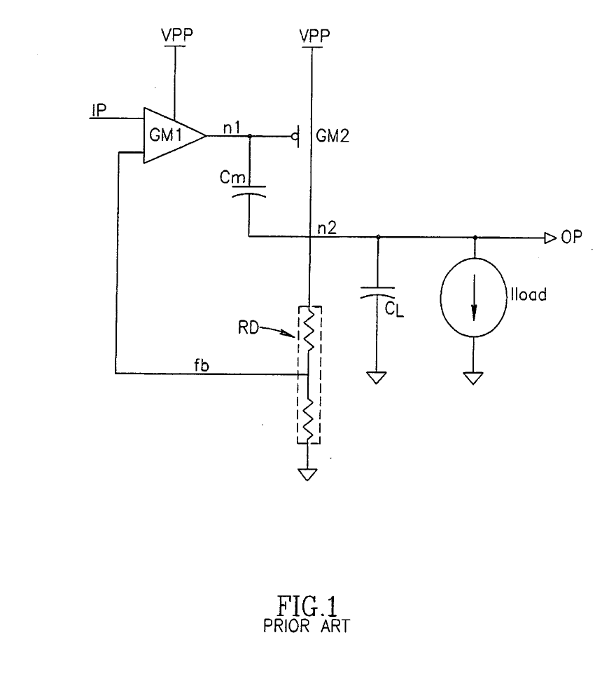

### DETAILED DESCRIPTION OF THE PRESENT INVENTION

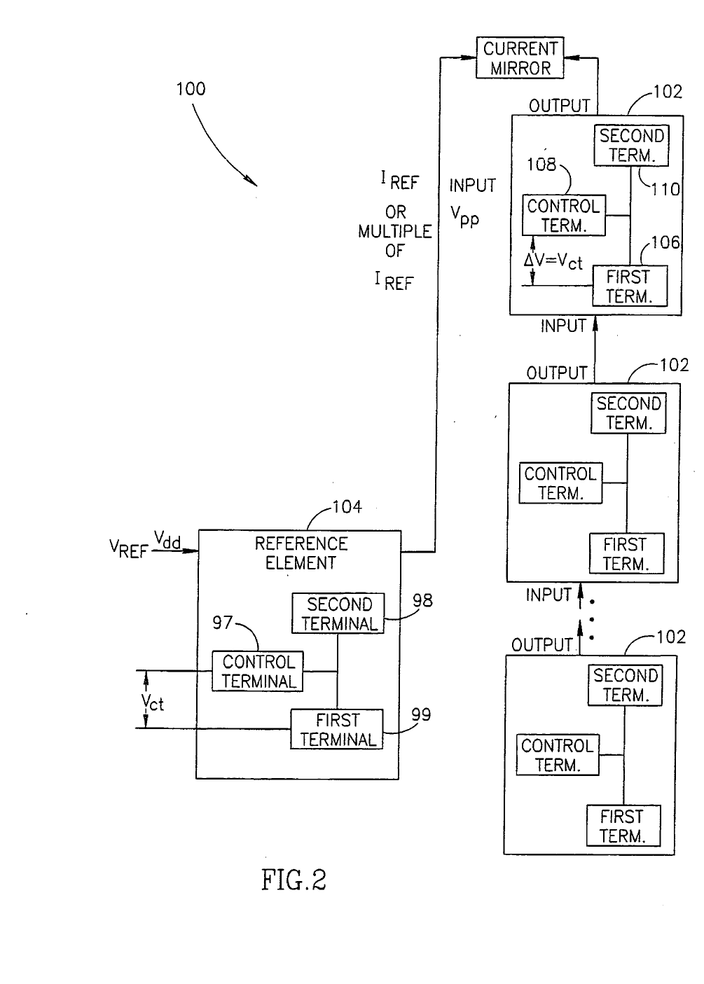

Reference is now made to FIG. 2, which illustrates a circuit 100 comprising stack elements 102, which may be used as a voltage regulator circuit, constructed and operative in accordance with a preferred embodiment of the present invention.

The circuit 100 may include a reference element 104 adapted to provide a reference current (I_{ref}) and having a control terminal 97, a first terminal 99 and a second terminal 98, there being a voltage (Vct) between the control terminal 97 and the first terminal 99 of reference element 104. Reference element 104 may comprise an NMOS transistor, in which case control terminal 97 comprises agate of the transistor, second terminal 98 comprises a drain of the transistor, first terminal 99 comprises a source of the transistor and Vct is the gate-source voltage (Vgs).

A plurality of series-connected stack elements 102 is preferably provided, wherein each stack element 102 comprises a first terminal 106, and a control terminal 108 connected to a second terminal 110. The stack elements 102 may receive the reference current Iref or a multiple thereof. The stack elements 102 and the reference element 104 are preferably matched. Two elements are considered “matched” if their lengths are substantially equal, and if their widths and current are either substantially equal or are the same multiple thereof. The stack elements 102 and the reference element 104 are preferably matched such that the voltage between the control terminal 108 and the first terminal 106 of one or all of the stack elements 102 is generally the same as the Vct of the reference element 104. (It is noted again that if reference element 104 is a transistor, then Vct=Vgs.) The output of a first stack element 102 is connected to the input of a subsequent stack element 102. The reference element 104 may be at a voltage Vdd and the stack elements may be at voltage Vpp wherein Vpp≧Vdd.

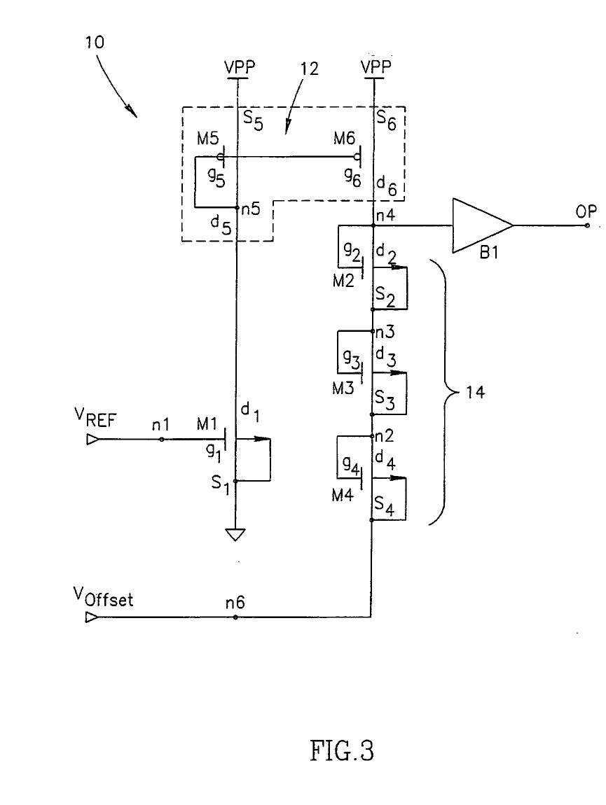

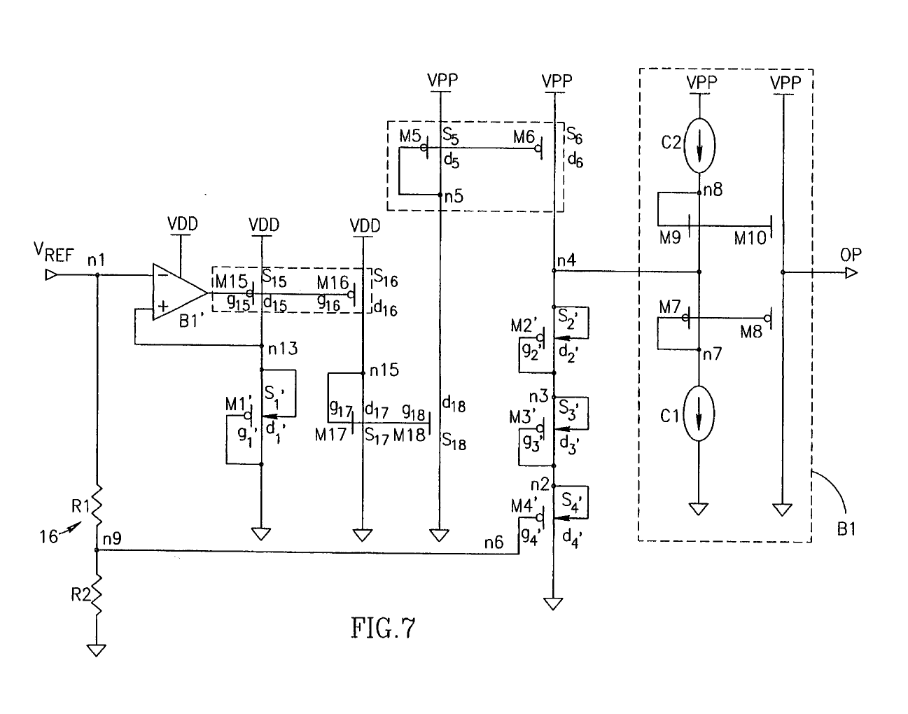

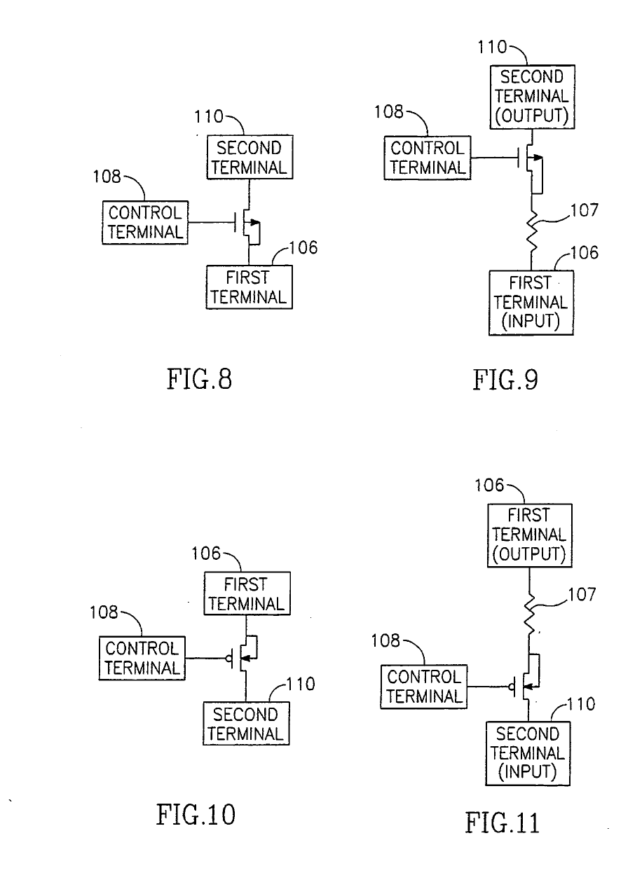

The circuit 100 may be implemented in several ways in accordance with the present invention. More detailed examples of a circuit wherein the stack elements 102 and the reference element 104 comprise NMOS transistors are described hereinbelow with reference to FIGS. 3-6. A more detailed example of a circuit wherein the stack elements 102 and the reference element 104 comprise PMOS transistors is described hereinbelow with reference to FIG. 7. Two simplified and general examples of circuits comprising NMOS transistors without and with a resistor are described hereinbelow with reference to FIGS. 8 and 9. Two simplified and general examples of circuits comprising PMOS transistors without and with a resistor are described hereinbelow with reference to FIGS. 10 and 11.

Reference is now made to FIG. 3, which illustrates an implementation of the circuit 100 of FIG. 2 in a voltage regulator 10 constructed and operative in accordance with a preferred embodiment of the present invention.

A reference voltage VREF may be input via a circuit node n1 into a gate g1 of an NMOS reference element M1. A source s1 and bulk of M1 are connected to GND. A drain d1 of M1 is connected at a circuit node n5 to a drain d5 and a gate g5 of a PMOS transistor M5, whose source s5 and bulk are at VPP. The gate g5 of M5 is connected to a gate g6 of a PMOS transistor M6, whose source s6 and bulk are at VPP. A drain d6 of M6 is connected at a circuit node n4 to a gate g2 and a drain d2 of an NMOS transistor M2. A source s2 and bulk of M2 are connected through a circuit node n3 to a gate g3 and a drain d3 of an NMOS transistor M3. A source s3 and bulk of M3 are connected at a circuit node n2 to a gate g4 and a drain d4 of an NMOS transistor M4. A source s4 and bulk of M4 may be connected at a circuit node n6 to a second input (a second reference voltage) VOFFSET. Circuit node n4 is also connected to an input of a driver B1, whose output is an output of a regulator OP. Transistors M5 and M6 form a current mirror 12. A current mirror is defined as a circuit element or portion of a circuit that receives an input current and outputs the same input current or a multiple thereof.

In accordance with a preferred embodiment of the present invention, the circuit of FIG. 3 is manufactured in a process that allows independent control of the NMOS bulk voltages. Examples of such processes are triple well processes, and silicon-on-insulator.

One operation of the circuit in accordance with an embodiment of the invention is as follows. The input reference voltage V_{REF}, which may typically be at a value of 1.3V, several 100 mV above the NMOS threshold voltage, isdnput to the gate g1 of M1. M1 then acts as a current source at its drain d1 providing a reference current Iref, which may typically be 5-10 μA. This current may be subject to process variations, but these generally do not affect the output voltage.

The current Iref is fed into the current mirror 12 formed by transistors M5 and M6. If transistors M5 and M6 are matched, the current at the drain d6 of M6 is Iref, or in general, at least a multiple thereof. The NMOS transistors M1, M2, M3 and M4 are all preferably matched. Since transistors M2, M3 and M4 are all diode connected (i.e., gate connected to drain) and have generally the same current as M1, their gate-source voltage (Vgs) is generally the same as the gate-source voltage of M1.

The transistors M2, M3 and M4 form a “stack” 14, that is, a plurality of series-connected stack elements, wherein each of transistors M2, M3 and M4 is a stack element. The voltage across stack 14 is the gate-source voltage Vgs multiplied by the number of transistors in the stack 14. In the illustrated embodiment, for example, since there are three transistors in the stack 14, the voltage between nodes n4 and n6 is three times V_{REF}. If a second reference voltage source, also referred to as an offset voltage V_{OFFSET}, is added at node n6, the voltage at n4 and OP is 3×V_{REF}+V_{OFFSET}. V_{OFFSET} may be equal to V_{REF} divided by a predetermined factor Y, as described hereinbelow. The value of OP may be increased/decreased by increasing/decreasing the number of transistors in the stack 14. In more general terms:

OP=(S×V_{REF})+(V_{REF}/Y) (1)

where S=the number of transistors in the stack 14 and Y is the divider ratio between V_{REF} and V_{OFFSET}.

In principle, any output voltage may be achieved by varying the number of transistors in the stack 14 and the divider ratio between V_{REF} and V_{OFFSET}. The driver B1 may be a class AB driver, which can drive the output strongly while using minimal quiescent current.

In accordance with embodiments described herein, transistor M2 is the “top” stack element, i.e., the first stack element to receive the reference current, and transistor M4 is the “bottom” stack element, i.e., the last stack element to receive the reference current.

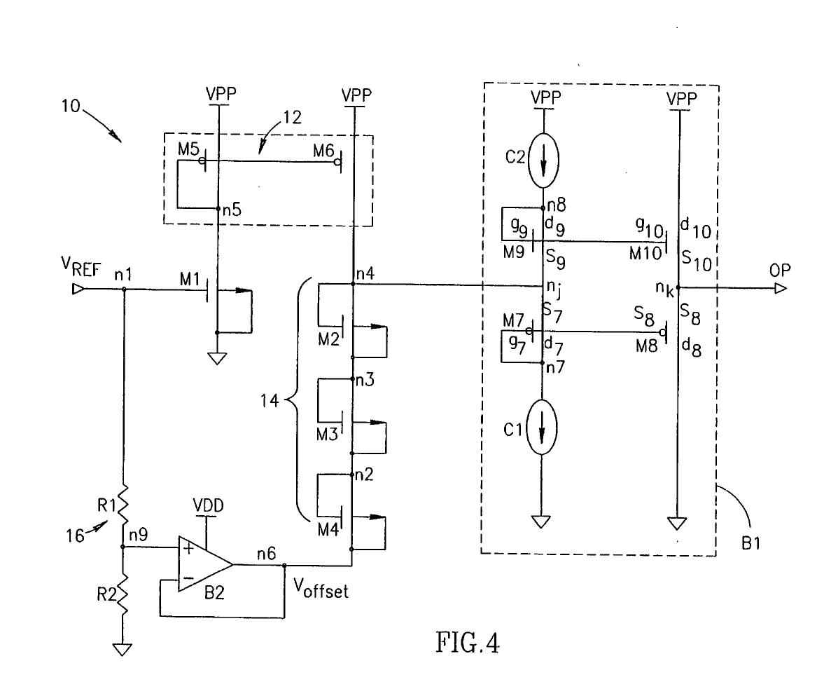

A more detailed version of the first embodiment is shown in FIG. 4. This schematic includes the circuit of FIG. 3, detailed circuitry of driver B1, as well as a circuit to generate the V_{OFFSET} input.

In the embodiment of FIG. 4, the driver B1 is formed by PMOS transistors M7 and M8, NMOS transistors M9 and M10, and current sources C1 and C2. A gate g7 and a drain d7 of M7 are connected via a circuit node n7 to current source C1. Current source C1 is grounded to GND. A source s7 of M7 is connected at a circuit node nj to a source s9 of transistor M9. The gate g9 of M9 and its drain d9 are connected to current source C2 via a circuit node n8. The current source C2 is connected to VPP. The gate g9 of M9 is connected to a)gate g10 of transistor M10, whose drain d10 is connected to VPP and whose source s10 is connected to OP via a circuit node nk. A gate g8 of M8 is connected to the gate g7 of transistor M7. A source s8 of M8 is connected to node nk, and a drain d8 of M8 is connected to GND.

The circuit to generate the V_{OFFSET} input preferably comprises a resistor divider 16. Resistor divider 16 may comprise, without limitation, a resistor R1 connected to V_{REF} via circuit node n1, and to a resistor R2 at circuit node n9. Resistor R2 is grounded to GND. A buffer B2 has a positive input connected to node n9, and a negative input connected to node n6, which, as described hereinabove, is connected to source s4 and bulk of M4.

In the driver B1 of FIG. 4, transistors M7, M8, M9 and M10 and current sources C1 and C2 preferably have equal current and are matched. C1 and C2 may be derived from Iref, or from another current reference. The current flowing in the stack 14 formed by transistors M2, M3, and M4 is generally unaffected by the presence of the current in current sources C1 and C2, because the two current sources compensate for each other. Thus, the voltage at n4 is still defined by equation 1.

Transistor M9 is diode connected, such that:

V(n₈)=V(n₄)+Vₜ+V_{dsat} (2)

where Vₜ is the threshold voltage of transistor M9 and V_{dsat} is the degree to which the transistor M9 is turned on beyond the threshold. According to basic MOSFET physics, the drain current I_{d} is described by;

I_{d}=k′W/L(V_{dsat}) (3)

where k′ is a process parameter, W and L are the width and length of the MOSFET and

V_{dsat}=V_{gs}−Vₜ (4)

with V_{gs} being the gate-source voltage.

Similarly, transistor M7 is diode connected and

V(n₇)=V(n₄)−Vₜ−V_{dsat} (5)

Transistors M8 and M10 are preferably back-to-back source followers and are matched with M7 and M9, respectively. The symmetry between the four transistors M7, M8, M9 and M10 causes:

a) OP to be generally at the same voltage as n₄ in steady state,

b) the current flowing in the M7, M9 branch to be generally equal to that in the M8, M10 branch in steady state, and

c) V_{dsat}(M8) to be generally equal to V_{dsat}(M7), and V_{dsat}(M9) to be generally equal to V_{dsat}(M10) in steady state.

If the voltage at OP differs from n₄, then the V_{dsat} of one of transistors M8 and M10 increases, whereas the V_{dsat} of the other transistor (M8 or M10) decreases, in accordance with equation 4. This results in a large current (in accordance with equation 3), which restores the equality between n₄ and OP. Thus the drive capability at OP may be very high. However, the quiescent currents of the circuit of FIG. 4 may be very low (˜20-30 μA).

The V_{OFFSET} input supplied at the source of M4 may be generated by resistor divider 16 from V_{REF}, which may be buffered by B2. It is noted that B2 may have VDD as the supply, such that the current drains caused by the buffer and the resistor divider 16 are less costly than those in the prior art.

A further enhancement of the voltage regulator of FIG. 3 or FIG. 4 is now described with reference to FIG. 5, which includes digital control circuitry 18.

Digital control circuitry 18 to generate the V_{OFFSET} input preferably comprises a resistor divider 20 that may comprise, without limitation, a resistor R1 connected to V_{REF} via circuit node n1, and to a resistor R2 at a circuit node n12. Resistor R2 is connected to a resistor R3 at a circuit node n11, and resistor R3 is connected to a resistor R4 via a circuit node n10. Resistor R4 is grounded to GND. An NMOS transistor M14 has its source s14 connected to node n12, its gate g14 connected to a digital input D1, and its drain d14 connected to node n9 via a circuit node nm. An NMOS transistor M13 has its source s13 connected to node n11, its gate g13 connected to a digital input D2, and its drain d13 connected to node n9 via node nm. An NMOS transistor M12 has its source s12 connected to node n10, its gate g12 connected to a digital input D3, and its drain d12 connected to node n9. As described hereinabove with reference to FIG. 4, buffer B2 has a positive input connected to node n9, and a negative input connected to node n6, which is connected to source s4 and bulk of M4. An NMOS transistor M11 has its source s11 connected to the gate g4 of transistor M4, its gate g11 connected to a digital input D4, and its drain d11 connected to node n6 via a circuit node ni.

In the embodiment of FIG. 5, digital inputs D1, D2, and D3 turn on/off transistors M12, M13, and M14, thus determining which voltage along the resistor divider 20 is input to buffer B2. In this manner, the V_{OFFSET} may be digitally controlled to be an arbitrary value between V_{REF} and GND, determined by the amount of digital inputs and transistors used. When the digital input D4 is enabled, transistor M11 shunts the Vgs of transistor M4. Thus, the number of transistors in the diode stack 14 may also be determined digitally. The embodiment of FIG. 5 allows digital control of the S and Y values in equation 1 for a given regulator. In an EPROM device, this may be a very useful feature to allow different trim levels for the wordline voltage.

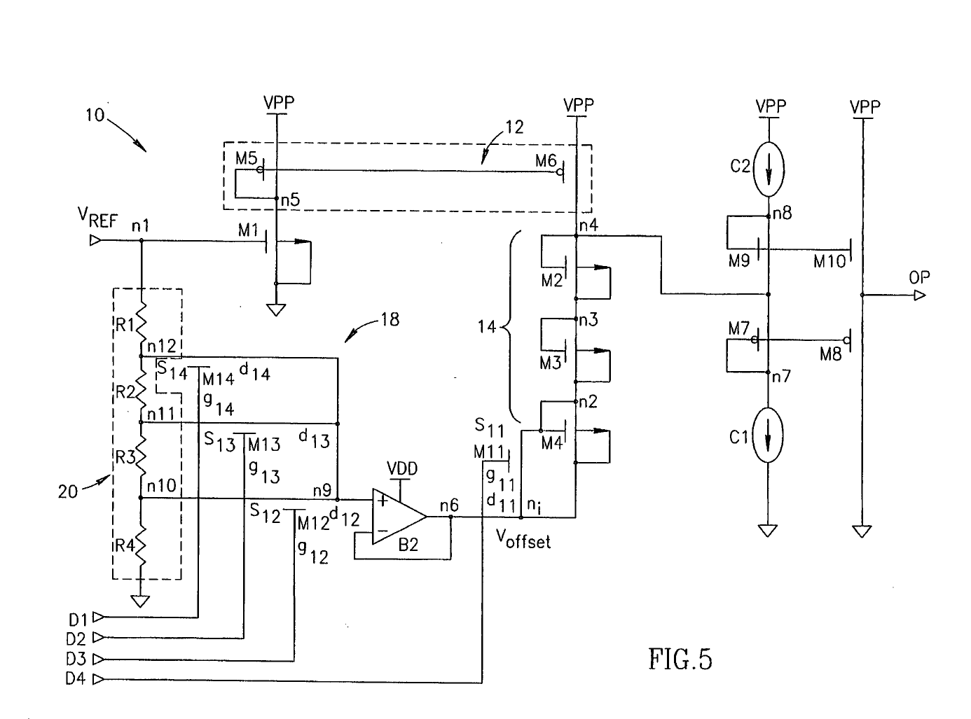

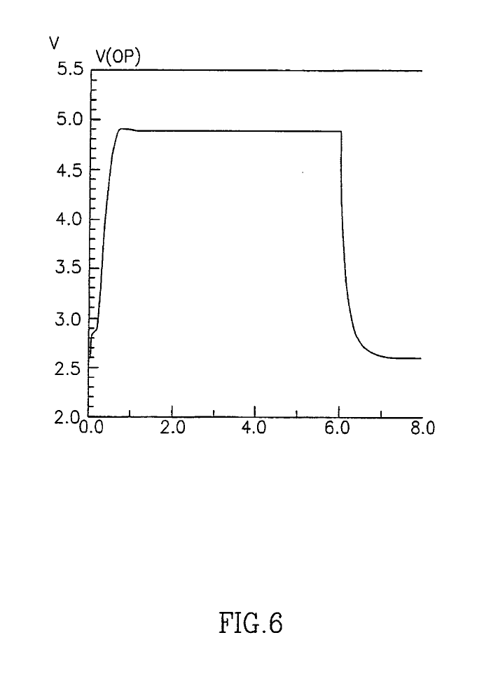

Reference is now made to FIG. 6, which illustrates a SPICE simulation of the rise and fall of OP for the circuit in FIG. 5. In the example of FIG. 6, OP is driven from VDD (2.6V) to 4.9V and back to VDD. The values of V_{REF} and V_{OFFSET} are 1.3V and 1V respectively. The output capacitance is 50 pF. The regulator raises V(OP) to its final value in <1 μs. This requires currents in the mA range. The quiescent current is 30 μA, typical of class AB operation. It is emphasized that these are only exemplary values, and the present invention is not limited to these values.

The circuits shown in FIGS. 3-5 all use NMOS transistors in the Vgs stack and to generate Iref. However, in order to have good Vgs matching between these transistors, it may be preferable to have independent control of the bulk voltage. In most CMOS process, all of the NMOS bulks may be permanently grounded, such that the Vgs voltages in the stack may differ as a result of the bulk effect. For these processes, it is possible to implement the regulator with another embodiment of the present invention, which uses PMOS transistors for the reference current and the Vgs stack, as is now described with reference to FIG. 7.

A gate g1′ and a drain d1′ of a PMOS reference element M1′ are connected to GND. A source s1′ of M1′ is connected at a circuit node n13 to the positive input of a comparator B1′ and to its bulk. A drain d15 of a PMOS transistor M15 is connected to node n13. A gate g15 of M15 is connected to output of comparator B1′ at a node n14, and to a gate g16 of a PMOS transistor M16. A source s15 of M15 is connected to VDD. A source s16 of M16 is connected to VDD. A gate g17 and a drain d17 of an NMOS transistor M17 are connected to a drain d16 of transistor M16 at a node n15. A source s17 of M17 is grounded to GND. The gate g17 of M17 is connected to a gate g18 of an NMOS transistor M18, whose source s18 is grounded to GND. A drain d18 of M18 is connected at node n5 to the drain d5 of PMOS transistor M5. Some of the transistors form current mirrors. For example, transistors M5 and M6 form a current mirror; transistors M15 and M6 form a current mirror, wherein transistor M15 is also used to generate the voltage at node n13; transistors M17 and M18 form a current mirror; and the combination of transistors M5, M6, M15, M16, M17 and M18 forms a current mirror that receives an input current from the reference element and outputs the same input current or a multiple thereof to the stack elements.

The drain d6 of M6 is connected at node n4 to a source and bulk s2′ of a PMOS transistor M2′. A gate g2′ and a drain d2′ of transistor M2′ are connected through node n3 to a source and bulk s3′ of a PMOS transistor M3′. A gate g3′ and a drain d3′ of transistor M3′ are connected through node n2 to a source and bulk s4′ of a PMOS transistor M4′. A gate g4′ of transistor M4′ is connected through node n6 to node n9, to which are connected resistors R1 and R2 of resistor divider 16. As described hereinabove with reference to FIG. 4, resistor divider 16 may comprise without limitation resistor R1 connected to V_{REF} via node n1, and to resistor R2 at node n9. Resistor R2 is grounded to GND. Comparator B1′ has a positive input connected to node n13, and a negative input connected to node n1. Comparator B1′ receives VDD. Driver B1 is connected to node n4 as described hereinabove with reference to FIG. 4.

The reference current, Iref, is generated across PMOS transistor M1′ in the embodiment of FIG. 7. Transistor M1′ is connected as a diode (gate to drain), and its source is driven by M15 at node n13. The source voltage of M1′ is fed back to the positive input of comparator B1′, which has its negative input at V_{REF}. The operational amplifier formed by B1′ and M15 equalizes the positive and negative inputs, such that V(n13)=V_{REF}. The current in M1′ (I_{ref}) is mirrored through transistors M16, M17, M18, M5 and M6 to the Vgs diode stack 14′ formed by M2′, M3′ and M4′. The voltage between the gate of M4′ and the source of M2′ is 3×V_{REF}, since M1′, M2′, M3′ and M4′ are matched in current and dimension. In addition, the offset voltage may be driven to the gate of M4 by the resistor divider 16 from V_{REF}, such that the voltage at n4 is defined by equation 1. The output buffer (i.e., driver) that is formed by current sources C1 and C2 and by transistors M7-M10 is generally identical to that shown in FIGS. 4 and 5. In principle, any output buffer (driver) may be used in the embodiment of FIG. 7, if and when necessary. The digital enhancements shown in FIG. 5 may also be implemented in the embodiment of FIG. 7. The circuit of FIG. 7 obeys equation (1).

As mentioned hereinabove, the circuit 100 may be implemented without and with a resistor in accordance with the present invention. For example, as shown in FIG. 8, the stack elements 102 and the reference element 104 of circuit 100 may comprise NMOS transistors. In such an embodiment, the control terminal 108 comprises the gate of the NMOS transistor, the first terminal 106 comprises the input which is the source and bulk of the NMOS transistor, and the second terminal 110 comprises the output which is the drain of the NMOS transistor, as described hereinabove with reference to the embodiment shown in FIG. 3.

Referring to FIG. 9, a resistor 107 may be connected between the source of the NMOS transistor and the first terminal 106. The bulk may be connected either to the source or the first terminal 106. Resistor 107 is preferably connected this way in the stack elements 102 and the reference element 104.

Reference is now made to FIG. 10, which illustrates another embodiment of the circuit 100, wherein the stack elements 102 and the reference element 104 comprise PMOS transistors. In such an embodiment, the first terminal 106 comprises an output comprising at least one of the source and bulk of the PMOS transistor, the control terminal 108 comprises the gate of the PMOS transistor, and the second terminal 110 comprises the input comprising the drain of the PMOS transistor, as described hereinabove with reference to the embodiment of FIG. 7.

Referring to FIG. 11, a resistor 107 may be connected between the source of the PMOS transistor and the first terminal 106. The bulk may be connected either to the source or the first terminal 106. Resistor 107 is preferably connected this way in the stack elements 102 and the reference element 104.

Connecting resistor 107 between the source of the transistor and the first terminal 106, as in FIGS. 9 and 11, may achieve a more uniform temperature coefficient of current for the reference and stack elements. In other words, the reference and stack currents may be more uniform over a wide range of temperature.

It will be appreciated by persons skilled in the art that the present invention is not limited by what has been particularly shown and described herein above. Rather the scope of the invention is defined by the claims that follow:

1-36. (Cancelled)

37. A driver comprising:
first and second PMOS transistors, first and second NMOS transistors, and first and second current sources, wherein a gate and a drain of said first PMOS transistor are connected to said first current source, and said first current source is grounded;
and wherein a source of said first PMOS transistor is connected to a source of said first NMOS transistor, said first NMOS transistor having its gate and its drain connected to said second current source, said second current source being connected to a supply voltage;
and wherein gates of said NMOS transistors are connected to each other, and gates of said PMOS transistors are connected to each other;
and wherein a drain of said second NMOS transistor is connected to said supply voltage and a source of said second NMOS transistor is connected to an output of said driver;
and wherein a drain of said second PMOS transistor is connected to GND, and a source of said second PMOS transistor is connected to the output of said driver.

38. The driver according to claim 37 wherein said first and second current sources are derivable from a reference current.

39. The driver according to claim 37 wherein said first and second current sources are generally equal.

40. The driver according to claim 37 wherein an input to said driver is connected to an output of a circuit comprising:
a reference element adapted to provide a reference current and having a control terminal and a first terminal, there being a voltage (V_{ct}) between said control terminal and said first terminal of said reference element; and
a plurality of series-connected stack elements, each said stack element comprising a first terminal connected to a first voltage, and a control terminal connected to a second terminal, said stack elements being adapted to receive at least one of said reference current and a multiple of said reference current, said stack elements and said reference element being matched such that a voltage between said control terminal and said first terminal of at least one of said stack elements is generally the same as V_{ct};
wherein a first reference voltage (V_{REF}) is input to said reference element; and
wherein a second reference voltage is input to said stack elements.

41-43. (Cancelled)
